(19) United States
(12) Patent Application Publication
(10) Pub. No.: US 2025/0285413 A1
(43) Pub. Date: Sep. 11, 2025

(54) MACHINE LEARNING FOR GENERATIVE GEOMETRIC MODELLING

(71) Applicant: ECOPIA TECH CORPORATION, Toronto (CA)

(72) Inventor: Yuanming Shu, Toronto (CA)

(21) Appl. No.: 18/860,493

(22) PCT Filed: Apr. 25, 2023
(86) PCT No.: PCT/IB2023/054242

§ 371 Date: Oct. 25, 2024

Related U.S. Application Data
(63) Continuation of application No. 17/731,769, filed on Apr. 28, 2022.
(60) Provisional application No. 63/335,464, filed on Apr. 27, 2022.
(60) Provisional application No. 63/370,830, filed on Aug. 9, 2022.

(51) Int. Cl. G06V 10/766; G06N 20/00; G06V 10/75; G06V 10/77; G06V 10/774; G06V 10/82

(52) U.S. Cl. CPC G06V 10/766; G06N 20/00; G06V 10/75; G06V 10/7715; G06V 10/774; G06V 10/82

(57) ABSTRACT

Example systems and methods for configuring machine learning models to generate geometric models are provided. An example method involves obtaining geometric modelling data comprising sequences of geometric modelling operations, and training the machine learning model on the geometric modelling data to generate geometric models encoded as tokenized representations of sequences of geometric modelling operations to be performed to build the geometric models, wherein the machine learning model is trained to generate the geometric models in accordance with learned geometric modelling practices extracted from the geometric modelling data.

### CROSS-REFERENCE TO RELATED APPLICATIONS

The present application claims priority to U.S. Provisional Patent Application No. 63/370,830, filed Aug. 9, 2022, entitled MACHINE LEARNING FOR GENERATIVE GEOMETRIC MODELING, and to U.S. Provisional Patent Application No. 63/335,464, filed Apr. 27, 2022, entitled MACHINE LEARNING FOR VECTOR MAP GENERATION, and to U.S. patent application Ser. No. 17/731,769, filed Apr. 28, 2022, entitled MACHINE LEARNING FOR VECTOR MAP GENERATION, each of which are incorporated herein by reference in their entireties.

### BACKGROUND

Structures and objects can be represented as geometric models in a wide a range of applications, including in computer-aided design (CAD) for manufacturing, engineering, and design, in geographic information systems (GIS) for modelling cities and environments, and in software development for game design and in designing augmented reality and virtual reality spaces, among other applications. Software platforms that allow individuals to manually design geometric models through a user interface by instantiating and manipulating various geometric entities are widely available. Geometric models may be conveniently represented mathematically as vector maps.

### BRIEF DESCRIPTION OF THE DRAWINGS

FIG. 1 is a schematic diagram of an example geometric modelling tool for generating training data for configuring a machine learning model to generate geometric models in accordance with learned geometric modelling practices.

FIG. 2A is a schematic diagram depicting an example of a geometric model being generated through a geometric modelling tool for the generation of training data. FIG. 2B depicts a record of a geometric modelling sequence recorded during the geometric modelling process. FIG. 2C depicts a tokenized representation that encodes for the recorded geometric modelling sequence.

FIG. 3 is a flowchart of an example method for configuring a machine learning model to generate geometric models in accordance with learned geometric modelling practices.

FIG. 4 is a schematic diagram of an example machine learning model for generating geometric models in accordance with learned geometric modelling practices, depicted during training.

FIG. 5 is a schematic diagram of an example machine learning model for generating geometric models in accordance with learned geometric modelling practices, depicted in operation.

FIG. 6A depicts an example geometric model derived from vector data generated in accordance with the systems and methods described herein. FIG. 6B depicts a corresponding graphical representation. FIG. 6C depicts a corresponding polygon set representation. FIG. 6D depicts a corresponding tokenized representation.

FIG. 7A depicts an example tokenized representation of a geometric modelling sequence. FIG. 7B depicts the progress of the generation of the corresponding geometric model at various stages.

FIG. 8A depicts another example tokenized representation representing a geometric modelling sequence. FIG. 8B depicts the progress of the generation of the corresponding geometric model at various stages.

FIG. 9A is a flowchart of an example method for generating a geometric model in accordance with learned geometric modelling practices for use in a geometric modelling environment. FIG. 9B is a schematic diagram depicting a system for generating geometric models for use in a geometric modelling environment.

### DETAILED DESCRIPTION

Geometric models can be manually generated using software platforms that allow individuals to manually design geometric models through a user interface. The geometric modelling process, however, can be a laborious task, especially when one wishes to design a wide range of objects and structures to create a realistic virtual space.

The present disclosure teaches the use of a machine learning model that is trained on geometric modelling data to generate novel geometric models at scale. The geometric modelling data that is used for training contains sequences of geometric modelling operations by which training samples were generated by actual users. These sequences of geometric modelling operations may reflect the use of a diverse range of geometric modelling techniques, including the use of a wide range of drawing elements (e.g., straight lines, curved lines, geometric primitives), the definition of attributes and spatial constraints, and manipulations of existing geometric entities, in the creation of such geometric models. Such practices may include the application of different geometric modelling techniques in different geometric modelling scenarios. A machine learning model trained on such geometric modelling data can be trained to generate new sequences of geometric modelling operations that produce novel geometric models in accordance with learned geometric modelling practices.

Since such geometric models are represented as geometric modelling sequences, each geometric modelling sequence will generally comprise a plurality of geometric modelling operations (e.g., creating and/or manipulating the various geometric entities that make up a geometric model) and a plurality of coordinates defining the vertices of the geometric entities that are being created and/or manipulated. As described herein, a machine learning model may be trained to directly generate such sequences of geometric modelling operations in a manner that captures learned geometric modelling practices involving the use of a variety of drawing elements (e.g., straight line segments, curves, etc.) and a variety of practices for defining attributes of geometric entities, including spatial constraints between geometric entities. The geometric modelling sequences that are produced may simulate the manner in which an actual user may generate such geometric models, including practices such as selecting and manipulating existing geometric entities, and defining geometric constraints among geometric entities. A machine learning model trained in this manner may produce novel yet realistic geometric representations of structures and objects at scale.

One type of machine learning model that may be particularly well-suited to this task includes autoregressive generative models, and in particular, autoregressive generative models that apply the concept of attention, such as a transformer model. These models may be particularly well-suited to capture the sequential nature of geometric modelling practices. Further, these models may be particularly well-suited to capturing the long dependencies inherent to large geometric models, and indeed, inherent to long sequences of geometric modelling operations.

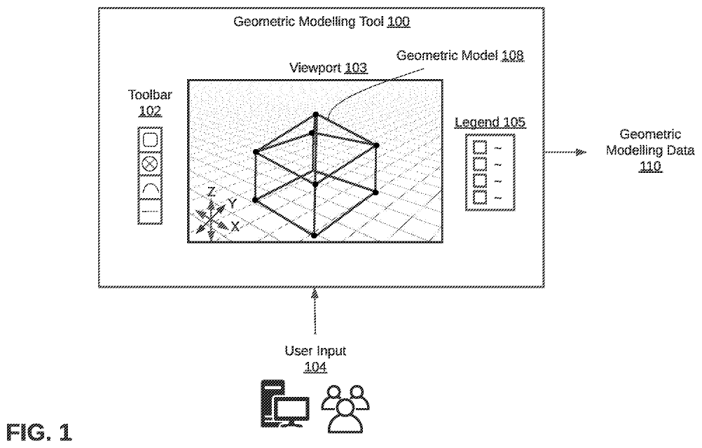

FIG. 1 is a schematic diagram of an example geometric modelling tool 100 for generating training data for training a machine learning model to generate geometric models in accordance with learned geometric modelling practices. The geometric modelling tool 100 may be understood to be one example of a geometric modelling tool (i.e., geometric modeling environment) to be used by human operators to generate geometric modelling data for the purposes of training such a machine learning model. Such training data may be used to train a machine learning model to generate geometric models of any sort of structure or object that can be created by a geometric modelling tool (e.g., models of buildings, trees, bridges, and other large outdoor structures, or models of chairs, tables, and other small or household objects).

The geometric modelling tool 100 may comprise one or more software modules embodied in non-transitory machine-readable instructions (e.g., software code) executable by one or more processors of one or more computing devices. The geometric modelling tool 100 shown by way of example here is particularly designed for use through a computing device capable of receiving input from a user through any suitable user input device (e.g., through mouse, keyboard, touchscreen, and the like) and capable of displaying imagery through a display device such as a computer monitor.

In operation, the geometric modelling tool 100 displays a user interface for performing geometric modelling to a user through any suitable display screen. The user interface of the geometric modelling tool 100 includes a viewport 103 through which the user may generate, view and interact with one or more geometric models 108, a toolbar 102 with which a user may select various tools for geometric modelling, and a legend 105 with which a user may define a particular class of object (e.g., to indicate that the user is generating a model of a roof to add context information).

In operation, a user may generate one or more geometric models 108 by making use of one or more of the user interface components, depicted here as the toolbar 102 an legend 105, which may allow the user to instantiate the various geometric entities that make up a geometric model (e.g., points, lines, curves, polygons, three-dimensional primitives, etc.), define various attributes of such geometric entities (e.g., size, position, orientation, scale, object class), manipulate such geometric entities (e.g., move, rotate), and define spatial constraints among such geometric entities (e.g., fixing relative positions of points, defining parallelism of lines, restricting movement of various geometric entities, etc.).

The geometric modelling tool 100 receives user input 104 (e.g., mouse and keyboard strokes performed at a computer terminal or other computing device) by which the user generates a geometric model 108 as described above. The geometric modelling tool 100 may record such user input 104 as raw data, or as a list of commands to instantiate, define and/or manipulate the various geometric elements and/or attributes and/or constraints that define such geometric models 108, shown here as geometric modelling data 110. Thus, the geometric modelling data 110 comprises a sequence of geometric modelling operations. The resulting sequence of geometric modelling operations may be understood as a sequence of commands or instructions that dictate how a geometric model is to be constructed.

In some examples, the geometric modelling data 110 may contain a detailed record of all user input received by the geometric modelling tool 100 (e.g., mouse movements, keyboard strokes, and the like). In other examples, the geometric modelling data 110 may contain only a higher-level record of the key commands issued by the user (e.g., create point, create line, define constraint, and the like). In other examples, the geometric modelling data 110 may contain a cleaned-up/streamlined sequence of operations that filters out redundant commands (e.g., a sequence of commands with edits and erasures like “undo” commands removed).

In some examples, context information may be processed and recorded by the geometric modelling 100 (e.g., by selecting a feature or object type from the legend 105 before or after modelling or by attributing a geometric entity with a particular object class) for training a machine learning model to generate geometric models of particular classes or types.

The recorded geometric modelling data 110 may be contributed to a library of training data that is used to train a machine learning model to generate geometric models in accordance with learned geometric modelling practices as described herein. Such training data may reflect the particular geometric modelling practices employed by the users generating the training data, such as applying different geometric modelling techniques in different geometric modelling scenarios, techniques for selecting and manipulating existing geometric entities, and techniques for defining geometric constraints among geometric entities, all of which may be extracted from training data and incorporated into a machine learning model to produce novel and realistic geometric models.

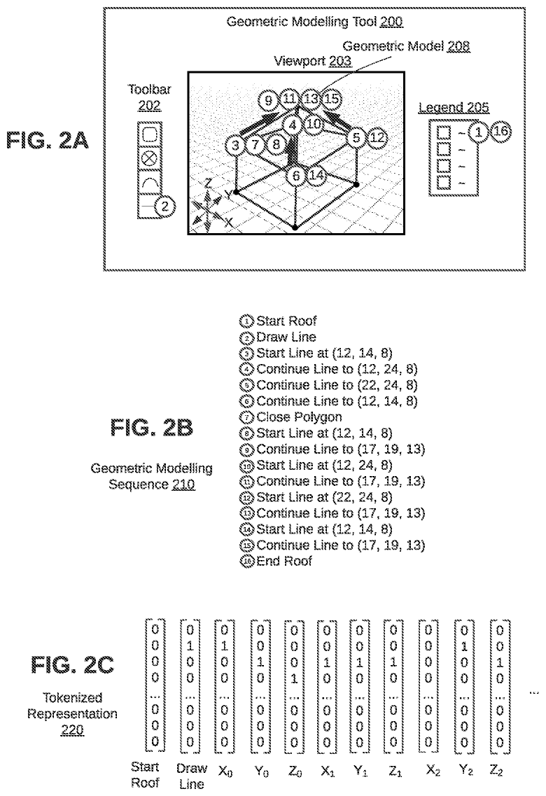

FIG. 2A is a schematic diagram depicting an example geometric modelling tool 200, similar to the geometric modelling tool 100 of FIG. 1, depicting a geometric model 208 being generated. As with the geometric modelling tool 100 of FIG. 1, the geometric modelling tool 200 of FIG. 2 comprises a user interface including a viewport 203, toolbar 202, and legend 205. In the present example, the geometric model 208 represents a simple square-based building with a pitched roof, but for simplicity, here we discuss the generation of only the roof portion of the building.

A sequence of geometric modelling operations performed by a user to build the geometric model 208 is illustrated as a series of actions (indicated by numbered “bubbles”) overlaying the user interface. As can be seen, the user begins building the roof structure by first selecting the “roof” button from the legend 205 (action 1), followed by the “draw straight line” tool from the toolbar 202 (action 2), then began outlining a polygon representing the outline of the roof structure through the viewport 203 (actions 3 through 7). The user then proceeds to draw four ridge lines stemming from the corners of the roof outline meeting together at a single point at the top of the roof (actions 8-9, 10-11, 12-13, and 14-15). The user then indicates that the roof structure is complete by again selecting the “roof” button in the legend 205 (action 16).

This sequence of geometric modelling operations is recorded and stored as geometric modelling sequence 210 shown in FIG. 2B. As can be see, the geometric modelling sequence 210 lists the types of geometric modelling operations performed (e.g., “start roof”, “draw line”, etc.), the coordinates of each point that is generated, and records this information in the order in which the geometric modelling operations were performed. The geometric modeling sequence 210 therefore captures an accurate record of the particular geometric modelling practices employed by the user.

The geometric modelling sequence 210 is encoded into a tokenized representation 220, shown in FIG. 2C. The tokenized representation 220 includes a series of operation tokes and coordinate tokens that encode for the sequence of geometric modelling operations employed by the user. In the present example, the tokenized representation 220 begins with the operation tokens “start roof” and “draw line” and proceeds with the coordinate tokens X₀, Y₀, and Z₀ representative of the X, Y, and Z coordinates of the first point created. The tokenized representation 220 continues to define the following operation tokens and coordinate tokens necessary to complete the geometric modelling sequence 210. Generally, the tokenized representation 220 is generated in a compact manner that can be interpreted according to a set of rules to yield a complete geometric modelling sequence.

The resulting tokenized representation 220 may be contributed to a library of training data to be used to train a machine learning model to generate geometric models in accordance with learned geometric modelling practices as described herein. Notably, the tokenized representation 220 captures not only the geometric information that defines the various geometric entities representing the geometric model 208 (e.g., the vertices of the geometric model 208 and their relative positions), but the tokenized representation 220 also captures the particular geometric modelling operations used to generate the geometric model 208, including any particular geometric modelling practices that were employed by the user. For example, in the present case, the user created the geometric model 208 of the roof of the building by first outlining the base of the roof (as opposed to starting with another part of the roof) and then proceeded to create individual ridge lines stemming from the base of the roof. This particular sequence of actions is captured in the tokenized representation 220. Thus, a machine learning model trained on the tokenized representation 220 may tend to build roof structures by first creating the outline of the roof and then adding the necessary ridge lines (as opposed to employing a different method). As will be discussed later in this disclosure, these kinds of geometric modelling practices, and other kinds of geometric modelling practices (e.g., the use of different drawing elements in different scenarios, selecting existing geometric entities for a particular purpose, defining constraints), all may be captured in a geometric modelling sequence 210 and incorporated into training.

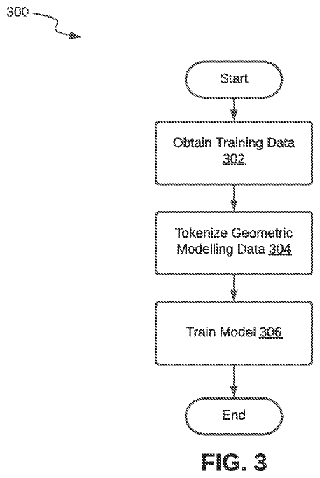

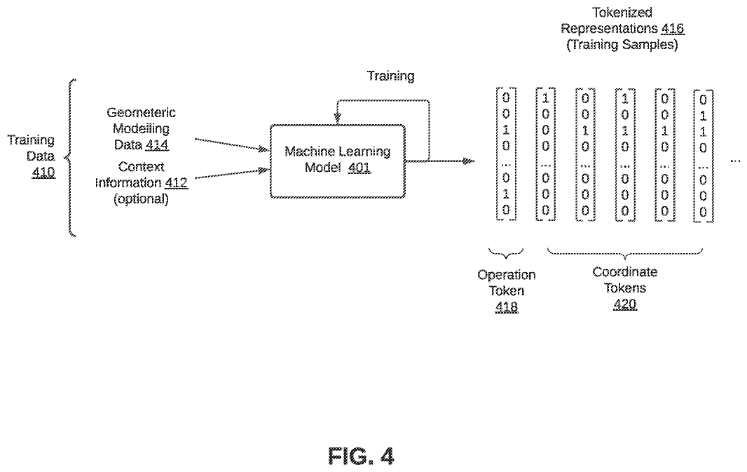

FIG. 3 is a flowchart of an example method 300 for configuring a machine learning model to generate geometric models in accordance with learned geometric modelling practices. For reference purposes, the method 300 is described with reference to FIG. 4, which is a schematic diagram of an example machine learning model 401 for generating geometric models in accordance with learned geometric modelling practices, depicted during training.

At operation 302, training data 410 is obtained. Training data 410 includes geometric modelling data 414, and, optionally, may include context information 412. The geometric modelling data 414 may include one or more sequences of geometric modelling operations by which one or more users have generated various geometric models for training purposes. For example, the geometric modelling data 414 may include the geometric modelling sequence 210 of FIG. 2B or a similar list of various geometric modelling operations carried out by users generating geometric models. When context information 412 is included to train a machine learning model to generate geometric models of particular classes, the context information 412 may be matched to the particular geometric modelling data 414 that corresponds to the generation of the appropriate object class. The training data 410 could include geometric modelling sequences used to generate any sort of structure or object that the machine learning model 401 is to be trained to reproduce (e.g., models of buildings, trees, bridges, and other large structures, or models of chairs, tables, and other small objects).

At operation 304, the geometric modelling data 414 is tokenized for machine learning purposes. For example, the geometric modelling data 414 may be tokenized into a form similar to the tokenized representation 220 of FIG. 2C. That is, the geometric modelling data 414 is converted into a form that describes the sequences of geometric modelling operations performed to generate such geometric models as a series of tokens. Such a tokenized representation will contain coordinate tokens and operation tokens that can be interpreted as a set of instructions for how geometric models are to be constructed. As described above, such a tokenized representation will reflect the various geometric modelling practices contained in the geometric modelling data 414.

At operation 306, the machine learning model 401 is trained on the training data 410. The machine learning model 400 is to be understood to comprise a deep learning model, and may include any suitable deep learning architecture such as one or more neural network layers, convolutional layers, attentive layers, and may comprise one or more blocks of several of such layers stacked on top of one another (e.g., in a transformer architecture). Further, the machine learning model 400 is to be understood to be an autoregressive model in that the elements of its output sequence are generated autoregressively based at least in part on the earlier-generated elements of the output sequence (i.e., tokenized representations 416).

The tokenized representations 416 of geometric modelling sequences comprise sequences of operation tokens 418 (e.g., draw line, define parallel) and coordinate tokens 420 (i.e., defining coordinates of geometric vertices), that may be interpreted as sequences of commands that may be employed to construct geometric models, which may ultimately be interpreted as the geometric models themselves. Once interpreted or made interpretable, such geometric models may be used in conventional geometric modelling environments, including GIS software, Computer-Aided Design (CAD) software, and the like.

Any appropriate machine learning training methods may be used to train the machine learning model 401, such as stochastic gradient descent. Since the tokenized representations 416 capture the order in which geometric modelling operations are to be performed, the machine learning model 401 may be trained to consider the order of its output tokens during training. Thus, the machine learning model 401 may be trained to minimize a cost function that defines error as being between the nth token in a training sample as compared to the nth token in a reference set, thereby capturing the error associated with coordinate tokens as well as operation tokens.

As described herein, since the training data 410 used to train the machine learning model 401 comprises labelled data (i.e., generated by user input), it is to be understood that the machine learning model 401 is trained by supervised learning. However, it is contemplated that in other examples, the machine learning model 401 may be trained or at least supplemented by semi-supervised training using artificially-generated datasets.

The method 300 and/or any of its steps (and the machine learning model 401) may be embodied in non-transitory machine-readable programming instructions and executable by one or more processors of one or more computing devices, such as servers in a cloud computing environment, which include memory to store programming instructions that embody the functionality described herein and one or more processors to execute the programming instructions.

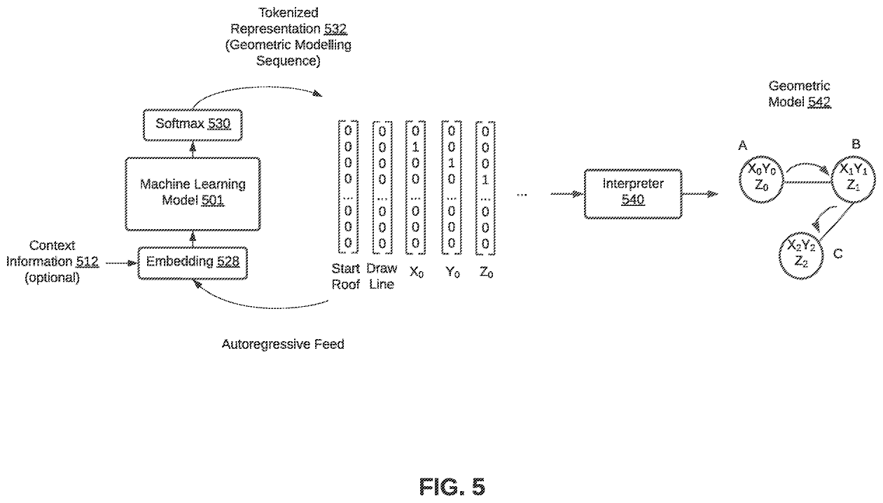

FIG. 5 is a schematic diagram of another example machine learning model 501 for generating geometric models in accordance with learned geometric modelling practices, depicted in operation. The machine learning model 501 may be similar to the machine learning model 401 of FIG. 4, and so, for further description of its components and/or its training, reference may be had to FIG. 4.

The machine learning model 501 is configured to autoregressively generate a tokenized representation 532 of a geometric modelling sequence (e.g., by a null token). Once initialized, the machine learning model 501 will probabilistically determine a first output token (e.g., in this case a “start roof” token, a kind of operation token), followed by another output token (e.g., in this case a “draw line token”, another kind of operation token), followed by another output token (e.g., in this case, coordinate token X₀), and so on, until the machine learning model 501 is finished producing the tokenized representation 532 (e.g., by selecting a “stop” token, not shown).

In the present example, the machine learning model 501 should be understood to apply self-attention among the elements of the autoregressively-generated tokenized representation 532. Thus, the probability that any given token will be selected as the next output token will vary based on the previously generated output tokens. If conditioned on context information 512 (optional) (e.g., “draw a building” or “draw a roof”), the machine learning model 501 may also apply cross-attention over a context token (i.e., apply attention between the context token and the elements of the output sequence), and produce the following output tokens accordingly.

As described with reference to FIG. 4, the machine learning model 501 may include any suitable deep learning architecture such as one or more neural network layers, convolutional layers, attentive layers, and may comprise one or more blocks of several of such layers stacked on top of one another. Further, the machine learning model 501 may include additional components such as an embedding layer 528 on the input, softmax function 530 on the output, and additional feed forward layers, skip connections, and other components in any suitable arrangement. In the present example, the machine learning model 501 will generally include at least one attentive layer to attend over the elements of the tokenized representation 532 as it is autoregressively generated. Such an attentive layer may apply attention in accordance with any known techniques, including as global attention, as local attention, clustered attention, or other techniques.

The tokenized representation 532 may be interpreted by an interpreter 540 that is configured to convert the geometric modelling sequence that is encoded for in the tokenized representation 532 into a usable format for a geometric model (i.e., indicated as geometric model 542, depicted in progress).

The tokenized representation 532 comprises operation tokens (e.g., “start roof”, “draw line”) and associated coordinate tokens (e.g., X₀, Y₀, Z₀). The coordinate tokens represent the vertices of the generated geometric model. The operation tokens represent the particular geometric modelling operations (i.e., the operation types) that are used to assemble the vertices together into the resulting geometric model, including operations to perform drawing actions that connect the vertices (e.g., straight line segments, curved line segments, geometric primitives, etc.), define the spatial constraints among them (e.g., parallelism), manipulate existing geometric entities, or other operations.

With a combination of coordinate tokens and operation tokens, the output tokenized representation 532 may encode for detailed design elements and realistic spatial constraints among geometric entities (e.g., the common geometric constraint that the three line segments that join at a corner of a building are perpendicular to one another, the line segments representing walls on opposite sides of a building are straight parallel lines, etc.). These kinds of spatial constraints would have been employed by users in generating training data and therefore may be extracted from such training data and incorporated into the machine learning model 501 as described herein. The use of operation tokens that represent specific geometric modelling operations in this manner enables the machine learning model 501 to build novel geometric models in a manner that accurately reflects the geometric modelling practices applied by users generating training data.

It is noteworthy that, since the machine learning model 501 is autoregressive and applies self-attention among the elements of the tokenized representation 532 (and, in some cases, cross-attention over a context token for particular structure types), the machine learning model 501 may learn to apply different geometric modelling techniques in different modelling scenarios. As an illustrative example, the machine learning model 501 may learn to follow certain geometric modelling procedures when modelling certain structure types, such as by building a roof model by first constructing the outline of the roof and then filling in the peaks and ridges that define its three-dimensional structure. Further, the machine learning model 501 may learn to construct the roof outline by sampling parallel and perpendicular lines (because building footprints are typically composed of parallel and perpendicular exterior walls), but may learn to sample ridge lines at various angles of inclination (because there is more variance in ridge line angle of inclination) within a learned range. Any of the geometric modelling operations described herein (e.g., selection operations, feature type definition, object manipulation) may be incorporated into such learned geometric modelling practices. Thus, the machine learning model 501 may learn to opt for different modelling techniques to build different model types, or different parts of the same model type, which may result in a more detailed and accurate reflection of the geometric modelling practices extracted from training data.

As mentioned previously, the output tokenized representation 532 may be made interpretable by conventional GIS software, CAD software, and the like, after further processing by an interpretation module, shown here as interpreter 540. The interpreter 540 is configured with a set of rules that provides a complete set of instructions for how to interpret the various coordinate and operation tokens produced by the machine learning model 500. In other words, the interpreter 540 is configured to convert, translate, decode, or otherwise interpret the output tokenized representation 532 as a vector map (i.e., a set of points, lines, and/or polygons or other geometric primitives, in some cases a polygonal mesh) representative of the geometric entities that comprise the geometric model being generated, into a format that is suitable for CAD software, GIS, and the like. Although the present example represents a three-dimensional geometric model, it is contemplated that two-dimensional geometric models can be generated in a similar manner.

The functionality of the machine learning model 501 (and any of its subcomponents), and/or the interpreter 540, may be embodied in programming instructions and executable by one or more processors of one or more computing devices, such as servers in a cloud computing environment, which include memory to store programming instructions that embody the functionality described herein and one or more processors to execute the programming instructions.

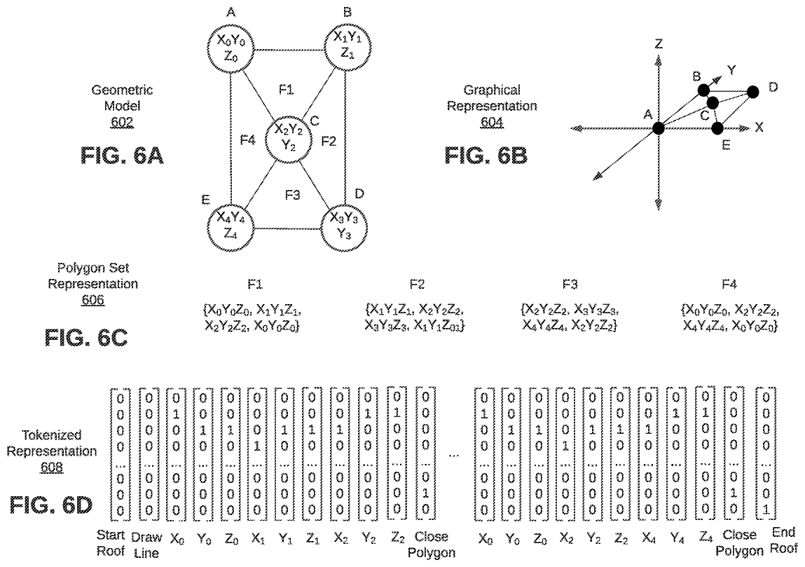

FIG. 6A depicts an example geometric model 602 derived from vector data generated in accordance with the systems and methods described herein. The geometric model 602 may be understood to represent, for example, a pitched roof structure of a building.

FIG. 6B, FIG. 6C, and FIG. 6D depict the corresponding graphical representation 604, polygon set representation 606, and tokenized representation 608, respectively. Notably, the geometric model 602 comprises five vertices, A, B, C, D, and E, which form four faces, F1, F2, F3, and F4. As can be seen from the tokenized representation 608, these four faces were generated one polygon after the other, with each polygon represented by at least one operation token (i.e., draw line, close polygon), and the associated sequences of coordinate tokens. Only the elements of the tokenized representation 608 that encode for faces F1 and F4 are shown for brevity.

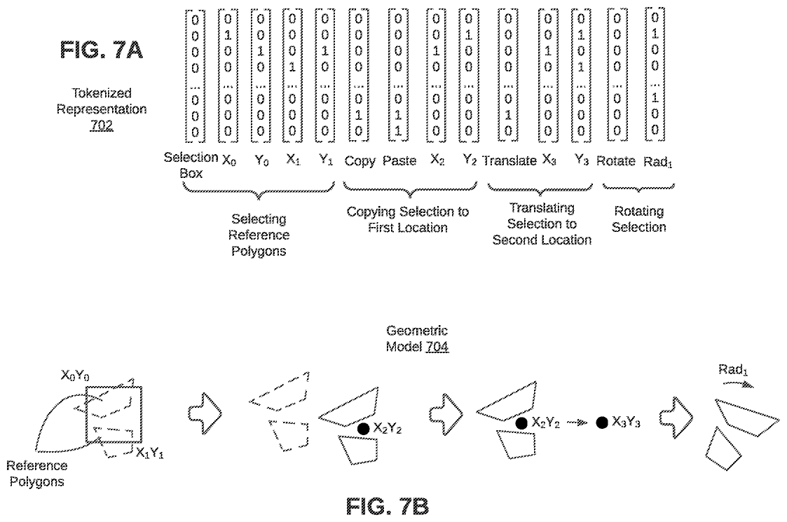

FIG. 7A depicts an example tokenized representation 702 representing a sequence of geometric modelling operations generated in accordance with the systems and methods described herein. FIG. 7B depicts the generation of the corresponding geometric model 704 at various stages.

Notably, the tokenized representation 702 includes operation tokens that represent various geometric manipulations made to various geometric entities. The examples provided herein are intended to represent, in a non-limiting manner, some of the ways in which more advanced geometric modelling operations may be encoded in training data and reproduced by a machine learning model in the generation of novel geometric models, as described herein. Although the present example depicts a two-dimensional geometric model 704, it is contemplated that the teachings herein may be applied to the manipulation of three-dimensional geometric models.

For example, the tokenized representation 702 begins with the use of what may be termed a “selection operation” or a “referencing operation”. That is, a geometric modelling operation that involves a geometric entity previously encoded for. Encoding for such selection operations directly within the tokenized representation 702 allows for advanced geometric modelling techniques to be extracted from training data, processed, and reproduced (i.e., simulated) by a machine learning model as described herein.

Here, a selection operation is used to select a group of pre-existing geometric entities (i.e., reference polygons). In some examples, a selection operation may involve defining one or more coordinates that corresponding to a geometric entity being selected. Here, the selection of the reference polygons is achieved by defining the vertices of a selection box that contains the selected geometric entities. This action is tokenized as a “selection box” token (i.e., a type of operation token) followed by a sequence of coordinate tokens that outlines the selection box containing the reference polygons (in this case, a selection box defined by points X₀Y₀ and X₁Y₁).

In another geometric modelling operation, following the selection of the reference polygons, the reference polygons are copied and pasted to another location. As with the above, the geometric practices associated with using such copy and paste operations may have been extracted from geometric modelling training data. In the present example, this action is tokenized as a “copy” token followed by a “paste” token followed by a sequence of coordinate tokens that indicates the desired copy-to location (X₂Y₂).

In yet another geometric modelling operation, following the copy and

pasting, the reference polygons are translated (i.e., shifted, moved) to another location, encoded for in the tokenized representation 702 with a “translate” token and a sequence of coordinate tokens that indicates the desired translate-to location (X₃Y₃).

In yet a further geometric modelling operation, the reference polygons

are rotated about a central point, encoded for in the tokenized representation 702 proceeds with a “rotate” token followed by a “rad₁” token indicating the desired radians by which the group of reference polygons are to be rotated. As with the above, the geometric practices associated with the application of such geometric transformations may have been extracted from geometric modelling training data.

Thus, tokenized representations may be produced that encode for geometric modelling operations that involves selecting geometric entities encoded for earlier in the tokenized representation. Previously defined geometric entities may be selected by defining one or more coordinates that corresponding to those geometric entities, thereby simulating a user actually selecting the geometric entities through a user interface.

Further, such geometric entities may be manipulated (e.g., rotated, translated, or otherwise transformed) directly in the tokenized representation. In some examples, a tokenized geometric modelling operation may involve defining an attribute of an existing geometric entity (e.g., defining a size or object type), and may even involve defining an attribute of an existing geometric entity with reference to another geometric entity (e.g., defining one line as parallel to another, defining one geometric primitive as having the same size or other dimension as another geometric primitive, or defining another geometric constraint among geometric entities). Thus, such advance geometric modelling practices may be directly incorporated into the training of a machine learning model.

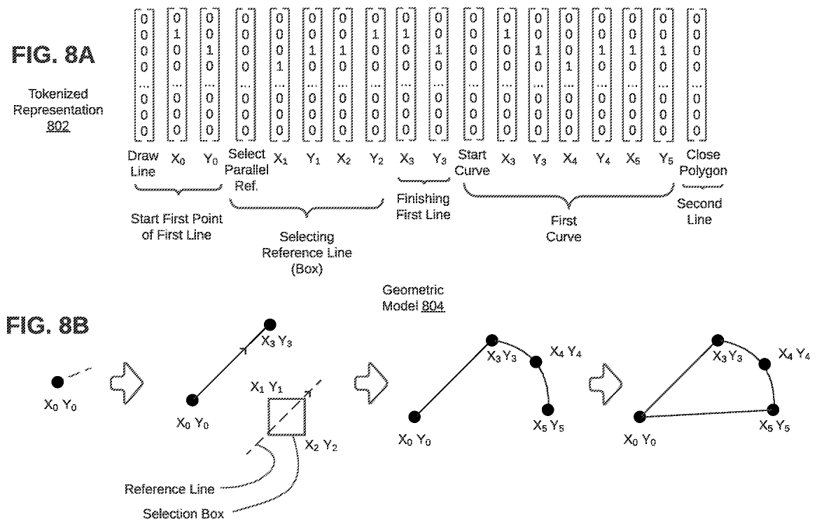

FIG. 8A depicts another example tokenized representation 802 representing another more advanced sequence of geometric modelling operations that may be produced in accordance with the systems and methods described herein. FIG. 8B depicts the generation of the corresponding geometric model 804 at various stages. Although the present example depicts a two-dimensional geometric model 804, it is contemplated that the teachings herein may be applied to the generation of three-dimensional geometric models.

The tokenized representation 802 and corresponding geometric model 804 represent a wedge-shaped polygon with one line defined as parallel to a pre-existing line that is present elsewhere in the modelling space. In particular, the line segment X₀, Y₀->X₃, Y₃ is defined as being parallel to an existing reference line by a selection operation. In the present example, the particular selection operation used is a selection box defined around the existing reference line. Such a selection operation may be replicated by a machine learning model trained on geometric modelling data as described herein. The use of a selection box is one example of a way in which a selection operation can be made by selecting an existing geometric element directly in the existing geometric modelling space as the geometric modelling data is being generated (i.e., a spatial selection operation). Other example selection operations are contemplated, such as the use of a selection line (drawing a selection line through a target reference object), a selection point (selecting a point directly on a target reference object), or a multiple-select operation (e.g., selecting points on multiple target reference objects, e.g., while holding down a particular input key such as the “shift” key).

Proceeding through the tokenized representation 802, it can be seen that the tokenized representation 802 begins with a “draw line” token followed by two coordinate tokens to instantiate a line segment beginning at a first point (X₀, Y₀). The tokenized representation 802 continues with a “select parallel reference” token, followed by a means for selecting a target reference geometry (in this case, a selection box from X₁, Y₁ to X₂, Y₂ selects a reference line). The tokenized representation 802 continues with a series of tokens that finishes the first straight line segment (in this case a coordinate token X₃, Y₃—but in other examples a single X or Y coordinate or a magnitude of the line segment may be used). Thus, a sequence of geometric modelling operations may include a selection operation with which a constraint on one geometric entity may be defined with respect to another geometric entity.

One way the preceding series of geometric modelling operations may have been carried out in training data is as follows: a user begins drawing a line by creating the first point (X0, Y0), and while the geometric modelling tool is expecting input for a second point, the user indicates that the line being drawn is to be made parallel to the existing reference line (e.g., by right clicking or otherwise indicating the reference line with the selection box), thereby narrowing the options for where the second point may land, and then proceeds to finish the first line segment by plotting the second point under that restriction (point X3,Y3). It is emphasized that such selection operations may be captured in training data in several different ways (as described above) and expressed by a machine learning model in operation tokens in several different ways.

The tokenized representation 802 then proceeds with the drawing of a curved line segment, from X3, Y3 through X4, Y4 to X5, Y5, and finishes with a “close polygon” token that can be interpreted as closing the polygon by drawing a second straight line segment from the last point in the sequence to the first point in the sequence.

The tokenized representation 802 provides an example output of a machine learning model trained to produce an output that not only represents an advanced geometric modelling procedure with several different types of drawing tokens (e.g., lines and curves), but which also is capable of encoding for geometric modelling practices that involve selection operations. That is, a machine learning model may be trained to make selection operations that refer to one or more previously defined geometric elements (e.g., to define a constraint), directly within its deep learning architecture, by generating selection tokens directly within the output tokenized representation.

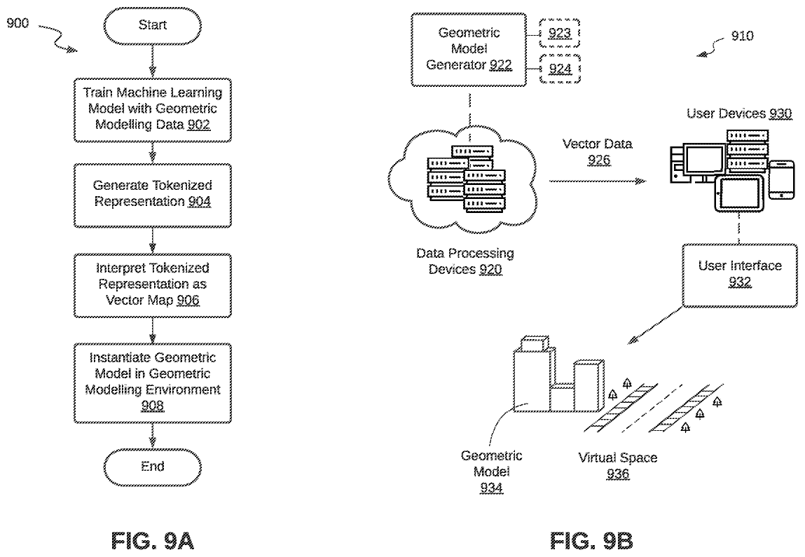

FIG. 9A is a flowchart of an example method 900 for generating a geometric model, in accordance with learned geometric modelling practices, for use in a geometric modelling environment. For illustrative purposes, the method 900 will be described with reference to the system 910 of FIG. 9B, which depicts a schematic diagram of an example system for generating geometric models in accordance with learned geometric modelling practices as described herein. However, the method 900 may be performed with other systems and/or devices.

First, a brief description of the system 910 of FIG. 9B is provided. The system 910 includes one or more data processing devices 920 that are configured to generate geometric models in accordance with learned geometric modelling practices as described herein. The data processing devices 920 include one or more computing devices, such as servers in a cloud computing environment.

The data processing devices 920 may store, host, access, run, or execute a geometric model generator 922 in order to generate geometric models as described herein. The geometric model generator 922 accesses a machine learning model 923, which may be similar to the machine learning model 401 of FIG. 4, the machine learning model 501 of FIG. 5, or as described elsewhere in this disclosure. The machine learning model 923 is trained on geometric modelling data to generate novel geometric models in accordance with learned geometric modelling practices. More specifically, the machine learning model 923 generates tokenized representations of geometric modelling sequences that can be converted into vector maps representative of geometric models. The geometric model generator 922 also accesses an interpreter 924 for this purpose, which may be similar to the interpreter 540 of FIG. 5, or as described elsewhere in this disclosure. The interpreter 924 interprets the tokenized representations generated by the machine learning model 922 into vector maps which may be represented as geometric models in conventional CAD and GIS systems and the like, as described herein. The geometric model generator 922 may be generally understood to comprise a set of non-transitory machine-readable programming instructions (e.g., software code) executable by one or more computing devices, such as the data processing devices 920.

The data processing devices 920 may include one or more communication interfaces to receive/obtain/access training data used to train the machine learning model 923, and to output/transmit vector data 926 representative of the geometric models generated by the geometric model generator 922 through one or more computing networks and/or telecommunications networks such as the internet. Such computing devices include memory to store programming instructions that embody the functionality described herein and one or more processors to execute such programming instructions.

The vector data 926 may be transmitted to one or more user devices 930, which may be used to store, view, manipulate, and/or otherwise use such vector data 926. For this purpose, the user devices 930 may store, host, access, run, or execute one or more software programs that process such vector data 926 (e.g., a CAD viewer). Thus, in the example shown, a user device 930 runs a software program comprising a user interface 932 through which one or more users may view the vector data 926. Further, such a user interface 932 may instantiate the vector data 926 (i.e., a geometric model 934 represented by the vector data 926), into a geometric modelling environment, shown here as virtual space 936, which may include a virtual reality space, an augmented reality space, a three-dimensional scene, a level in a game, and the like. In the present example, the geometric model 934 is a building structure, and the virtual space 936 includes an exterior scene depicting a road and surrounding buildings. The vector data 926 may be delivered to user devices 930 in any suitable format through any suitable delivery means, including as batch files or through an application programming interface (API).

Such vector data 926 may be particularly useful for city planning, land use planning, architectural and engineering work, for environmental assessments, for virtual reality or augmented reality, for automated vehicle navigation, for the generation of a digital twin of a city, and the like.

Returning to the method 900 of FIG. 9A, at operation 902, the machine learning model 923 is trained to generate tokenized representations of geometric modelling sequences for geometric models based on geometric modelling data, as described elsewhere in this disclosure.

At operation 904, a tokenized representation of a geometric model (e.g., geometric model 934) is generated (i.e., sampled) from the machine learning model 923. Such an operation may be controlled by the geometric model generator 922, and may or may not be conditioned on context information.

At operation 906, the interpreter 924 interprets the tokenized representation as vector data 926 representative of a geometric model (e.g., geometric model 934). That is, the interpreter 924 interprets the set of coordinate tokens and operation tokens into a form suitable for conventional CAD and GIS software and the like.

At operation 908, the user devices 930, through user interface 932, instantiate the geometric model 934 into a geometric modelling environment. As shown here, the geometric model 934 depicts a building structure to be used in an exterior scene. Such geometric models 934 may be contributed toward a digital twin of a city, used in a virtual reality, augmented reality, or other virtual application, or used for city planning, land use planning, architectural and engineering work, and the like.

Thus, the systems and methods described herein may be applied to train machine learning models on geometric modelling data to automatically generate geometric models in a manner that captures learned geometric modelling practices. Machine learning models trained in such a way that emulates how a human would generate such geometric models using a variety of drawing elements and defining various spatial constraints directly within deep learning architecture. The machine learning models applied may include autoregressive generative models that apply aspects of attention for their capability to capture long dependency relationships present in such geometric modelling data. Applications of such systems and methods include city and environmental planning, the generation of digital twins for cities, the generation of novel geometric models for augmented reality and virtual reality purposes, among other applications.

It should be recognized that features and aspects of the various examples provided above can be combined into further examples that also fall within the scope of the present disclosure. The scope of the claims should not be limited by the above examples but should be given the broadest interpretation consistent with the description as a whole.

1. A method for configuring a machine learning model to generate geometric models, the method comprising:
obtaining geometric modelling data comprising sequences of geometric modelling operations; and
training the machine learning model on the geometric modelling data to generate geometric models encoded as tokenized representations of sequences of geometric modelling operations to be performed to build the geometric models;
wherein the machine learning model is trained to generate the geometric models in accordance with learned geometric modelling practices extracted from the geometric modelling data.

2. The method of claim 1, wherein the sequences of geometric modelling operations of the geometric modelling data comprises training data derived from user input into a geometric modelling tool.

3. The method of claim 2, wherein a tokenized representation of a geometric model generated by the machine learning model comprises:
a plurality of coordinate tokens representing vertices of the geometric model; and
one or more operation tokens representing one or more geometric modelling operations involving one or more of the vertices of the geometric model.

4. The method of claim 3, wherein the geometric model comprises a plurality of geometric entities, and wherein the tokenized representation encodes for a geometric modelling operation that involves selecting a geometric entity encoded for earlier in the tokenized representation.

5. The method of claim 4, wherein the selection of the geometric entity involves defining one or more coordinates that correspond to the geometric entity.

6. The method of claim 4, wherein the geometric modelling operation involves transforming the geometric entity.

7. The method of claim 4, wherein the geometric modelling operation involves defining an attribute of a first geometric entity with respect to a second geometric entity.

8. The method of claim 7, wherein the attribute is a geometric constraint.

9. The method of claim 1, wherein the learned geometric modelling practices extracted from the geometric modelling data comprise tendencies to apply different geometric modelling techniques in different geometric modelling scenarios.

10. The method of claim 1, wherein the machine learning model comprises an autoregressive generative model.

11. The method of claim 1, wherein the machine learning model is configured to apply self-attention among the elements of the tokenized representation.

12. The method of claim 11, wherein the machine learning model is further configured to apply cross-attention between the elements of the tokenized representation and a context token.

13. A method for generating geometric models, the method comprising:
applying a machine learning model to generate a tokenized representation of a geometric model, wherein the tokenized representation of the geometric model defines a sequence of geometric modelling operations that is to be performed to build the geometric model.

14. The method of claim 13, further comprising:
converting the tokenized representation of the geometric model into a format suitable for use in a geometric modelling environment; and
instantiating the geometric model in a geometric modelling environment.

15. The method of claim 13, wherein the machine learning model is trained to generate tokenized representations of geometric models of particular object classes.

16. The method of claim 13, wherein the machine learning model is trained to generate tokenized representations of building structures.

17. A system for configuring a machine learning model to generate geometric models, the system comprising one or more computing devices configured to:
obtain geometric modelling data comprising sequences of geometric modelling operations; and
train the machine learning model on the geometric modelling data to generate geometric models encoded as tokenized representations of sequences of geometric modelling operations to be performed to build the geometric models;
wherein the machine learning model is trained to generate the geometric models in accordance with learned geometric modelling practices extracted from the geometric modelling data.

18-20. (canceled)
